(19) United States
(12) Patent Application Publication
(10) Pub. No.: US 2015/0289348 A1
(43) Pub. Date: Oct. 8, 2015

(54) CONTROL DEVICE AND METHOD FOR DATA TRANSMISSION VIA A LOAD LINE

(71) Applicant: TRIDONIC GMBH & CO KG, Dornbirn (AT)

(72) Inventors: Kai Airbinger, Hard (AT); Simon Lecker, Dornbirn (AT); Roman Ploner, Hohenems (AT)

(21) Appl. No.: 14/440,328

(22) PCT Filed: Nov. 6, 2013
(86) PCT No.: PCT/AT2013/000184

§ 371 Date: May 1, 2015

(30) Foreign Application Priority Data
Nov. 6, 2012 (AT) GM 432/2012.6

(51) Int. Cl. H05B 37/02; H05B 33/08; G01R 25/00

(52) U.S. Cl. CPC H05B 37/0254; G01R 25/00; H05B 33/0815; H05B 33/0851

(57) ABSTRACT

A data transmission from a control device (100) to a load (52) is carried out via a load line (40). The control device (100) comprises a first switching means (121) and a second switching means (122) which are switched in a series circuit between an input terminal (101) and an output terminal (102) of the control device (100). A control circuit (110) is coupled to the first switching means (121) and the second switching means (122) and is configured to generate a control signal (ctrl) for controlling the first switching means (121) and/or the second switching means (122) so as to transmit data bits.

### FIELD OF THE INVENTION

The invention relates to a device and a method for controlling an operating device for an illuminant. The invention relates, in particular, to methods and devices in which a data packet can be transmitted via a load line via which energy is supplied.

### BACKGROUND

Dimmers can be used for the brightness control of illuminants. In the case of luminaires operating on the basis of conventional illuminants such as incandescent bulbs, the brightness regulation in the dimmer can be carried out by means of a phase gating or phase cutting of the supply voltage of the luminaire. In this case, the power of the luminaire is reduced by a momentary interruption of the supply voltage being brought about after or before the zero crossing of the supply voltage, such that the power of the luminaire is reduced depending on the time duration of the interruption.

Control devices can be used for brightness or color control in order to communicate control signals to an operating device for an illuminant. An evaluation circuit provided in the operating device evaluates said control signals and correspondingly sets the brightness. Such a control can also be used for color control. Such a type of control is suitable in particular for lighting devices based on illuminants in the form of gas discharge lamps or light emitting diodes (LEDs).

For data transmission via the load line, a line path between an input terminal and an output terminal of a control device connected between a supply source and a load can be switched into a high-impedance state. As a result, a control signal can be modulated onto a supply voltage of the load. Fundamental restrictions of a power switch, such as the integrated diode between source and drain of a power MOSFET, can make it more difficult to efficiently transmit data bits via the load line. Devices and methods for data transmission via a load line are desirable in which, during the transmission of a data packet, more than one data bit per full cycle of the supply voltage is also possible, in principle.

It is an object of the invention to provide a device and a method for data transmission via a load line which are suitable for use for luminaires based on non-conventional illuminants and allow efficient data transmission via a load line.

### SUMMARY

This object is achieved by means of a control device, a method and a lighting system comprising the features specified in the independent claims. The dependent patent claims define developments of the invention.

In accordance with one exemplary embodiment, a control device is specified which is configured for data transmission via a load line. The control device has an input terminal for coupling to a supply source, for example a power supply system voltage source, and an output terminal for coupling to the load line. The control device comprises a first switching means and a second switching means, which are connected in a series circuit between the input terminal and the output terminal. The control device comprises a control circuit, which is coupled to the first switching means and the second switching means and which is configured to generate a control signal for controlling the first switching means and/or the second switching means for the purpose of transmitting data bits.

The use of two switching means makes it possible to generate a phase gating and/or a phase cutting for coding a data bit both in the case of a half-cycle of the supply voltage having a positive sign and in the case of a half-cycle of the supply voltage having a negative sign. It is possible to transmit two data bits per full cycle of the supply voltage. A data packet can be transmitted with a sequence of half-cycles of the supply voltage. In this case, an actuation value for the operating device, for example a target value for a brightness or color, can be coded by the phase gating or phase cutting of a plurality of successive half-cycles.

The control device can be used in particular for transmitting a data packet to an operating device for an illuminant. The data packet can comprise a brightness value and/or color value. The operating device for the illuminant can carry out a brightness or color control or a brightness or color regulation depending on the actuation value transmitted in the data packet. The brightness or color predefined by the data packet can be maintained by the operating device after the transmission of the data packet has been concluded. Unlike in the case of conventional phase-cutting dimming or phase-gating dimming, after transmission of the data packet no further phase gating or phase cutting have to be generated in order for example to maintain a reduced brightness.

The first switching means and the second switching means can be configured such that they are in an on state in order to conductively connect the input terminal to the output terminal if a signal is present at the input terminal and the control circuit does not generate the control signal. The control circuit has to generate the control signal selectively only if phase gating and/or phase cutting are generated in order to transmit a data packet or if some other measure, for example an identification of the zero crossing of the supply voltage, requires switching into the high-impedance state.

The first switching means and the second switching means can be power switches. The first switching means and the second switching means can be power semiconductor components having an insulated gate electrode, for example MOSFETs.

The control circuit can be configured to influence a potential at a gate of the first switching means and at a gate of the second switching means only if the control device outputs the control signal. The control circuit, by virtue of the generation of the control signal, can bring about a change in potential at the gates of the first switching means and of the second switching means, which increases the resistance of the series circuit. As a result, a supply voltage provided to the load can be momentarily reduced in order to generate a phase gating or phase cutting.

The control device can comprise circuit components coupled to the input terminal and serving for charging a gate of the first switching means and a gate of the second switching means. The circuit components can form a charging circuit, which charges the gate of the first switching means and the gate of the second switching means such that both switching means are in an on state and allow a current flow between input terminal and output terminal.

The control circuit can be configured to cause a discharge of the gate of the first switching means and of the gate of the second switching means by generating the control signal. The control circuit can control a pull-down circuit via which a potential at the gates of the first switching means and of the second switching means is changed. The control circuit can be configured to feed the control signal to a gate of a transistor connected in series with a pull-down resistor.

The control device can comprise at least one energy storage means configured to charge a gate of the first switching means and a gate of the second switching means. The energy storage means can be coupled to the input terminal via a first diode and to the output terminal of the control device via a second diode. Such an energy storage means, which can comprise one capacitor or a plurality of capacitors, for example, helps to switch the series circuit formed by the first switching means and the second switching means into an on state again rapidly. The control circuit can be configured for controlling a further switching means, which is connected between the energy storage means and the gates of the first switching means and of the second switching means. As a result, charging of the gates of the first switching means and of the second switching means can be prevented if the series circuit is intended to be switched into a high-impedance state.

The control circuit can be configured to switch the series circuit formed by the first switching means and the second switching means into a high-impedance state multiply for the purpose of transmitting a sequence of data bits. The control circuit can be configured to generate phase gating and/or phase cutting depending on data to be transmitted, in order to transmit the sequence of data bits.

The control circuit can be configured to identify a phase angle of a supply voltage of the supply source and to generate the control signal in predefined time windows before or after zero crossings of the supply voltage. The control circuit can be configured to initiate a procedure for identifying a zero crossing of the supply voltage of the supply source if a data packet is intended to be transmitted. The control circuit can be configured to switch the series circuit formed by the first switching means and the second switching means into an off state and to monitor a voltage detected in the control device while the series circuit is switched into the off state, in order to identify the zero crossing of the supply voltage. The control circuit can be configured to switch the series circuit formed by the first switching means and the second switching means into the off state at an instant at which a current flowing from the supply source to the load via the control device has a zero crossing.

The control circuit can be configured to switch the series circuit formed by the first switching means and the second switching means into the high-impedance state twice per full cycle of the supply voltage. The control device can be configured to switch the series circuit formed by the first switching means and the second switching means into the high-impedance state both in the case of a half-cycle of the supply voltage having a positive sign and in the case of a half-cycle of the supply voltage having a negative sign. As a result, one data bit can be coded per half-cycle of the supply voltage.

The control device can comprise a setting element. The control circuit can be configured to monitor an actuation of a setting element of the control device. The setting element can comprise for example one pushbutton switch or a plurality of pushbutton switches, a rotatable setting element or other actuatable elements. The control circuit can selectively initiate a procedure for transmitting a data packet which includes the switching of the series circuit formed by the first and second switching means into a high-impedance state, if an actuation of the setting element was identified. An internal supply voltage for the operation of the control circuit can be generated from the voltage dropped between input terminal and output terminal of the control device. The control device can be configured such that the control circuit is supplied with energy selectively only if an actuation of the setting element is identified.

The control device can be a dimmer by means of which a brightness value is settable.

According to a further exemplary embodiment of the invention, a method for data transmission from a control device to a load is specified. In the method, phase gating and/or phase cutting for half-cycles of a supply voltage are generated by means of the control device according to one exemplary embodiment in order to code a sequence of data bits. The method can be used in particular for transmitting a data packet to an operating device for an illuminant.

According to a further exemplary embodiment, a lighting system is specified. The lighting system comprises at least one operating device for an illuminant and a control device according to one exemplary embodiment. The control device is coupled to the at least one operating device via a load line.

The at least one operating device can comprise an evaluation circuit, which checks a supply voltage for presence of phase gating and/or phase cutting. The evaluation circuit can be configured to check half-cycles of the supply voltage having a positive sign and also half-cycles of the supply voltage having a negative sign with regard to the presence of a phase gating and/or phase cutting. The evaluation circuit can be configured to determine a dimming value and/or a color value from a sequence of phase gating and/or phase cutting which are modulated on a sequence of half-cycles of the supply voltage. The evaluation circuit can be configured to read out in each case one data bit of a data packet per half-cycle of a sequence of half-cycles. The evaluation circuit of the operating device can be configured to perform a brightness change and/or color change depending on the sequence of phase gating and/or phase cutting after the data packet has been transmitted.

The at least one operating device can comprise at least one LED converter.

### BRIEF DESCRIPTION OF THE DRAWINGS

Further features, advantages and functions of exemplary embodiments of the invention will become apparent from the following detailed description with reference to the accompanying drawings, in which identical or similar reference signs designate units having an identical or similar function.

FIG. 1 shows a lighting system comprising a control device according to one exemplary embodiment of the invention.

FIG. 2 is a flowchart of a method according to one exemplary embodiment.

FIG. 3 shows a time-dependent profile of a supply voltage if a control device according to one exemplary embodiment generates phase cutting for the purpose of transmitting a data packet.

FIG. 4 is a circuit diagram of a control device according to one exemplary embodiment.

FIG. 5 shows circuit components of a control device according to one exemplary embodiment.

FIG. 6 is a circuit diagram of a control device according to one exemplary embodiment.

FIG. 7 shows circuit components of a control device according to one exemplary embodiment for elucidating the functioning of the control circuit.

FIG. 8 is a circuit diagram of a control device according to one exemplary embodiment for elucidating an identification of a zero crossing of a supply voltage.

FIG. 9 is a flowchart of a method according to one exemplary embodiment.

FIG. 10 shows a time-dependent profile of a current flowing through the control device to the load and of a detected voltage for elucidating the functioning of the control device.

### DETAILED DESCRIPTION OF THE PREFERRED EMBODIMENTS

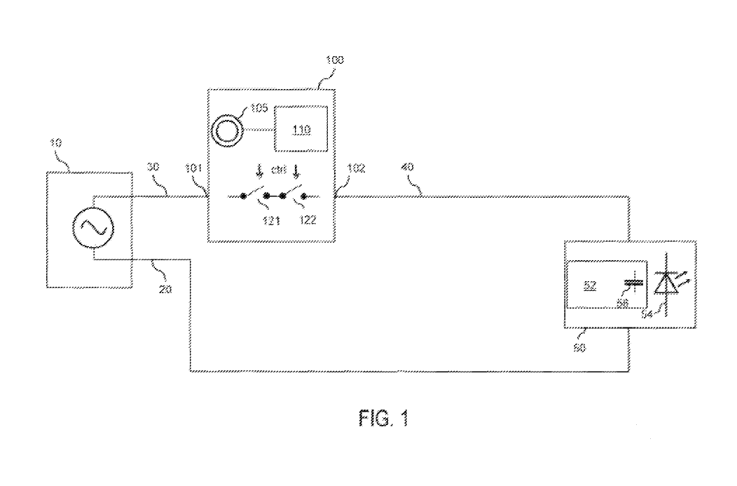

FIG. 1 illustrates a lighting system comprising a control device 100 according to one exemplary embodiment of the invention. The lighting system comprises the control device 100, a supply source 10, for example a power supply system voltage source, and one luminaire 50 or a plurality of luminaires 50. The luminaire 50 is controlled by the control device 100. For this purpose, the control device 100 transmits a data packet via a load line. For the purpose of transmitting a plurality of data bits of the data packet, the supply voltage is influenced by the control device 100 in a manner temporally coordinated with zero crossings of the supply voltage, for example for the purpose of generating phase gating or phase cutting of half-cycles of the supply voltage. In the explanations below it will be assumed that the control device 100 serves for controlling the brightness of the lighting device 50, i.e. is configured as a dimmer. The control device 100 can also be usable for alternative or additional control processes, for example for color control.

The luminaire 50 comprises an operating device 52 and an illuminant 54. The illuminant 54 can comprise one or a plurality of light emitting diodes (LEDs). The operating device 52 can correspondingly be configured as an LED converter. It goes without saying here that the illuminants 54 can be implemented in various ways, e.g. by one or a plurality of inorganic LEDs, organic LEDs, gas discharge lamps or other illuminants. Furthermore, a combination of the abovementioned types of illuminant can also be used. Suitable operation of the respective illuminant 54 is effected by means of the operating device 52. For this purpose, the operating device 52 can comprise a power supply unit, for example, which generates a suitable voltage and/or a suitable current from a supply voltage fed to the luminaire for the purpose of operating the illuminant 54. For non-conventional illuminants, for example for LEDs, the operating device 52 constitutes a non-ohmic load. By way of example, an interference-suppression capacitor 56 connected to the inputs of the operating device 52 can bring about a phase shift between current and supply voltage.

A power supply system voltage conductor 20 proceeding from the power supply system voltage source 10 is connected to the luminaire 50. A further power supply system voltage conductor 30 proceeding from the power supply system voltage source 10 is connected to the control device 100. The power supply system voltage conductor 20 can be a neutral conductor, while the power supply system voltage conductor 30 is a phase conductor. The control device 100 is connected to the luminaire 50 via a load line 40. The luminaire 50 is coupled to the power supply system voltage conductor 20 and the load line 40 and takes up its supply voltage via the load line 40 and the power supply system voltage conductor 20. The supply voltage of the operating device is thus fed to them via, on the one hand, the power supply system voltage conductor 20 and, on the other hand, via the power supply system voltage conductor 30, the load line 40 and the control device 100 coupled therebetween. The control device 100 is directly connected only to one of the power supply system voltage conductors 20, 30. A connection of the control device 100 to the neutral conductor is not necessary, which reduces the installation outlay.

The control device 100 comprises a control circuit 110 and a setting element 105. The control circuit 110 has the task of influencing a supply voltage for the luminaire 50 in a targeted manner such that a plurality of data bits of a data packet are transmitted via the load line 40. By way of example, half-cycles with phase gating and/or phase cutting can be generated for this purpose. For this purpose, the control circuit 110 can comprise a first switching means 121 and a second switching means 122 in a series circuit. The first switching means 121 and the second switching means 122 can be configured as power switches, for example as MOSFETs, or other power semiconductor components. If the first switching means 121 is a first MOSFET and the second switching means 122 is a second MOSFET, the switching means 121, 122 can be provided such that a source terminal of the first switching means 121 is coupled to a source terminal of the second switching means 122. The control circuit 110 can drive the series circuit formed by the first switching means 121 and the second switching means 122 by generating a control signal ctrl such that at least one of the two switching means 121, 122 is switched into a high-impedance state. A current flow through the series circuit can thus be greatly suppressed or substantially completely eliminated if the control circuit 110 generates the control signal ctrl.

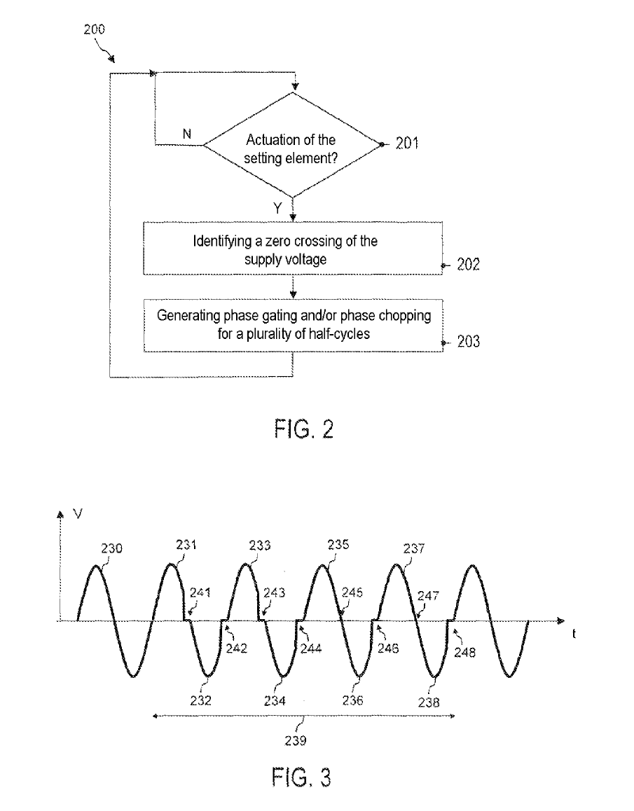

As is described in even greater detail with reference to FIG. 2 to FIG. 10, the control circuit 110 can control the first switching means 121 and the second switching means 122 in order to reduce a supply voltage provided to the luminaire 50 during a predefined time window of a half-cycle of the supply voltage. In particular, the control circuit 110 can switch one of the switching means 121, 122 into a high-impedance state in order to generate a phase gating and/or phase cutting of a half-cycle of the supply voltage having positive signs. The control circuit 110 can switch the other of the switching means 121, 122 into a high-impedance state in order to generate a phase gating and/or phase cutting of a half-cycle of the supply voltage having a negative sign. Furthermore, the control circuit 110 can implement a method for identifying a zero crossing of the supply voltage. For this purpose, the control circuit 110 can likewise control the switching means 121, 122 such that the series circuit formed by the first switching means 121 and the second switching means 122 has a high resistance and interrupts a current flow between an input terminal 101 and an output terminal 102 of the control device 100 for a time interval. On the basis of the result of the identification of the zero crossing of the supply voltage, the control circuit 110 can modulate phase gating and/or phase cutting on a plurality of half-cycles in order to transmit a data packet via the load line 40.

The corresponding data packet with which the control device 100 controls the luminaire 50 can be influenced by actuation of the setting element 105. The setting element 105 can comprise a pushbutton switch, for example. Upon actuation of the setting element 105, a sequence of half-cycles with phase gating and/or phase cutting can be generated in order to transmit a data packet which causes the luminaire 50 to change the brightness. By way of example, by means of actuations of the setting element 105, the brightness can be increased by one step in each case until a maximum brightness is reached, and afterward, by means of actuations of the setting element 105, the brightness can in turn be reduced by one step in each case until a minimum brightness is reached. Furthermore, upon permanent actuation of the setting element 105, the brightness can automatically be varied in a periodic manner and the brightness set when the setting element 105 is released can be maintained. It goes without saying that there are furthermore diverse further possibilities for controlling the luminaires 50 by means of the setting element 105. The setting element 105 can for example also comprise a potentiometer coupled to a rotary head by means of which the desired brightness is settable. In this case, upon actuation of the setting element 105, the control device 100 can detect the position of the potentiometer and, by means of the control circuit 110, generate a data packet for setting the corresponding brightness and communicate it to the luminaire 50.

FIG. 2 is a flowchart of a method 200 which can be performed automatically by the control device 100. In the method, step 201 involves monitoring whether the setting element 105 of the control device 100 is actuated. If an actuation of the setting element 105 is identified, step 202 involves performing a procedure which ascertains an instant at which the supply voltage has a zero crossing. A phase angle of the supply voltage can be determined as a result. The determination of the zero crossing of the supply voltage that is performed in step 202 enables a reliable transmission of a data packet even if a non-ohmic load is connected to the load line. In step 203, using the zero crossing of the supply voltage identified in step 202, the supply voltage is influenced in a targeted manner in order to transmit a data packet. By way of example, phase gating and/or phase cutting can be generated in predefined time intervals after or before a zero crossing of the supply voltage. The data packet can comprise a value coded in a bit sequence, for example a dimming value and/or a color value. The data packet can be generated depending on a dimming value or color value set by means of the setting element 105.

While FIG. 2 schematically illustrates a method in which an actuation of the setting element 105 in step 201 initiates the determination of the phase angle of the supply voltage and the transmission of a data packet, the performance of the method can also be initiated by other events. This may be the case for example upon automatic dimming or automatic color control in accordance with a timing sequence schedule.

FIG. 3 illustrates how the control device 100 generates phase cutting for the purpose of data transmission. For this purpose, the control circuit 110 switches in each case at least one of the first switching means 121 and the second switching means 122 into an off state in a manner temporally coordinated with the zero crossings of the supply voltage. A supply voltage 230 provided to the operating device 52 of the luminaire has a plurality of half-cycles 231-238. A plurality of the half-cycles have phase cutting. The phase cutting is generated by the control device 100 such that a logic “0” or a logic “1” can be coded for example by the presence or absence of a phase cutting in the case of a half-cycle. A first half-cycle 231 of the sequence of half-cycles can have a phase cutting 241. A start bit of a data packet can be coded thereby. At least one half-cycle 238 of the sequence of half-cycles can have a phase cutting 248 in order to indicate the end of the data packet. For the intervening half-cycles 232-237, phase cutting can be generated selectively in order to transmit a dimming value, a color value or some other bit sequence. By way of example, one bit value, e.g. a logic “1”, can respectively be coded by means of the phase cutting 242, 243, 244 and 246 of the half-cycles 232, 233, 234 and 236. Another bit value, e.g. a logic “0”, can respectively be coded by the absence of phase cutting 245 and 247 in the case of the other half-cycles 235 and 237. Other configurations are possible. By way of example, instead of a target value for a brightness or a color, which target value is intended to be approached by the operating device in a changeover process, it is also possible merely to communicate information in the data packet about whether a brightness value, a color value or some other manipulated variable is intended to be incremented or decremented. As illustrated schematically in FIG. 3, during the transmission of the data packet phase cutting or phase gating can be generated both for half-cycles having a positive sign and for half-cycles having a negative sign. This allows the transmission of two data bits per full cycle of the supply voltage, while the data packet is transmitted. In further configurations, it is also possible to transmit fewer than two data bits per full cycle. The data packet is transmitted in a time duration 239. Afterward, no further phase gating and/or phase cutting need be generated until, for example, a data packet has to be sent again. Control of the light emission of the illuminant in accordance with the command communicated in the data packet is carried out by the operating device of the illuminant after the end of the time duration 239, i.e. after the transmission of the data packet.

The operating device 50 has an evaluation circuit, which monitors the received supply voltage for the presence of phase gating and/or phase cutting. The evaluation circuit can identify the start of a data packet on the basis of at least one phase gating or phase cutting. The evaluation circuit can ascertain the control command communicated with the data packet, for example a target value of a manipulated variable. The operating device implements the control command, for example by approaching the target value of the manipulated variable with a changeover time. If a command for incrementing or decrementing the manipulated variable is transmitted with the data packet, said command being coded in a sequence of phase gating and/or phase cutting, the operating device can likewise carry out a corresponding changeover process. An implementation of the command contained in the data packet by the operating device 52 can begin after the data packet has been completely received by the operating device 52. A data packet having a target value for a manipulated variable has to be communicated only if the target value changes. The control device 110 does not have to continuously modulate phase gating and/or phase cutting onto the supply voltage in order that the illuminant is operated with reduced brightness, for example.

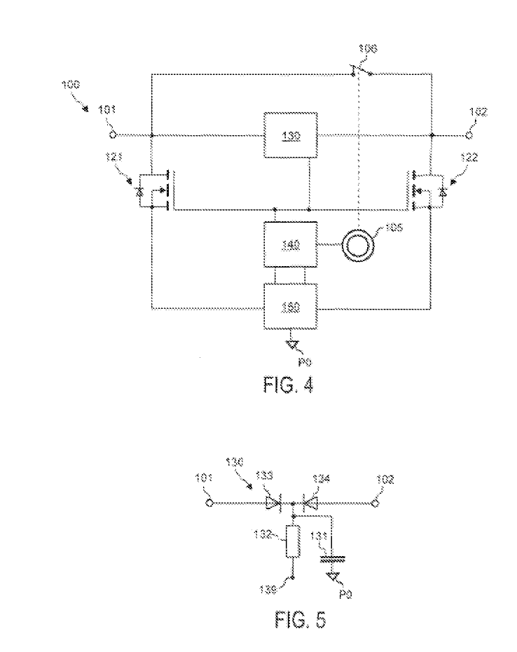

As is described in even greater detail below with reference to FIG. 4 to FIG. 7, the control circuit 110 can control the first switching means 121 and the second switching means 122 such that, independently of the respective phase angle of the supply voltage, in each case one of the switching means 121, 122 is in a high-impedance state, while the control circuit 110 generates a corresponding control signal ctrl in order to switch the line path between input terminal 101 and output terminal 102 with high impedance. By way of example, the series circuit formed by the first and second switching means 121, 122 can comprise two normally off re-channel MOSFETs which are coupled to one another at their source terminals. The control circuit 110 can instigate a discharge of the gates of the MOSFETs in order to switch the series circuit into a high-impedance state independently of the current flow direction through the MOSFETs.

As has been explained with reference to FIG. 1, the control device 100 can comprise a series circuit comprising a first switching means and a second switching means, said series circuit being connected between the input terminal 101 and the output terminal 102 of the control device. The first switching means and the second switching means can in each case be a power MOSFET or comprise a power MOSFET. The power MOSFETs can be coupled to one another at their source terminals or at their drain terminals. Such configurations make it possible, in a particularly simple manner, by means of two power switches in a series circuit, to generate phase gating or phase cutting both for half-cycles of the supply voltage having a positive sign and for half-cycles of the supply voltage having a negative sign. Configurations of such control devices are described in greater detail with reference to FIG. 4 to FIG. 7. In this case, similar reference signs designate similar elements or assemblies.

FIG. 4 is a circuit diagram of a control device 100 according to one exemplary embodiment. The control device 100 comprises a first switching means 121 and a second switching means 122. The first switching means 121 and the second switching means 122 are connected in a series circuit between the input terminal 101 and the output terminal 102 of the control device 100. The control device 100 comprises a control circuit 140, which is configured to switch in each case at least one of the two switching means 121, 122 into an off state.

The first switching means 121 and the second switching means 122 can be configured in each case as a power MOSFET. Other power switches, in particular power semiconductor components having an insulated gate electrode, can be used. In this case, the first switching means 121 and the second switching means 122 can be switched such that the forward directions of the fundamentally integrated diodes of the power MOSFETs for the two switching means 121, 122 are opposite to one another. For this purpose, by way of example, the first switching means 121 and the second switching means 122 can be embodied in each case as an n-channel MOSFET. The source terminals of the two n-channel MOSFETs can be coupled to one another.

The first switching means 121 and the second switching means 122 can be in an on state if a signal from the supply source is received at the input terminal 101 and a control circuit 140 does not discharge the gates of the power MOSFETs. A charging circuit 130 can be used to charge the gates of the first switching means 121 and of the second switching means 122. The charging circuit 130 can be coupled to the input terminal 101 and the output terminal 102. The charging circuit 130 can act in the manner of a pull-up circuit by means of which the potential at the gates of the power MOSFETs is raised to a specific value. The charging circuit 130 can be configured to charge the gates of the first switching means 121 and of the second switching means 122 in order to switch both switching means 121, 122 into an on state. The charging circuit 130 can comprise a capacitor or some other energy storage means in order to charge the gates of the first switching means 121 and of the second switching means 122 again relatively rapidly. Phase gating or phase cutting with relatively steep voltage edges can be generated in this way.

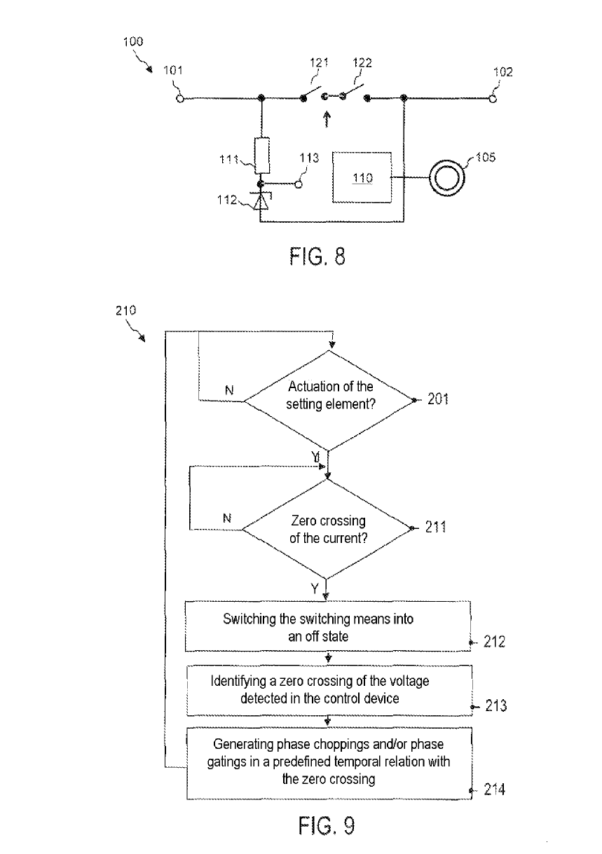

The control circuit 140 can be coupled to the gates of the first switching means 121 and of the second switching means 122 in order to control a discharge of the gates. The series circuit formed by the first switching means 121 and the second switching means 122 can thereby be switched selectively into a high-impedance state. As described with reference to FIG. 1 to FIG. 3, the control circuit 140 can switch the series circuit formed by the first switching means 121 and the second switching means 122 into an off state in time windows that are shorter than a half-cycle of the supply voltage, in order to generate phase gating and/or phase cutting. Furthermore, the control circuit 140 can switch the series circuit formed by the first switching means 121 and the second switching means 122 into an off state in order to carry out a procedure for determining a zero crossing of the supply voltage. For this purpose, the control circuit 140 can bring about a discharge of the gates of the first switching means 121 and of the second switching means 122 in order to switch off a current flow through the control device, as described in even greater detail with reference to FIG. 8 to FIG. 10. In order to perform the various functions mentioned, the control circuit 140 can comprise at least one logic circuit, which can be configured as an integrated circuit. The control circuit 140 can comprise at least one microprocessor or controller in order to perform the functions mentioned.

An internal supply voltage for the control circuit 140 can be generated from the voltage dropped in the control device. For this purpose, provision can be made of a supply circuit 150 for the energy supply of the control circuit 140. The supply circuit 150 can comprise a plurality of zener diodes, for example, in order to provide the internal supply voltage for the control circuit 140. The control device 100 can also be configured such that a bridging contact 106 of the setting element 105 bridges the input terminal 101 and the output terminal 102 as long as the setting element 105 is not actuated. What can be achieved in this way is that the control circuit 140 is supplied with voltage only upon actuation of the setting element 105, such that a power consumption of the control device 100 is reduced.

The functioning of the control device 100 during the generation of phase gating and/or phase cutting for transmitting a sequence of data bits corresponds to the functioning described with reference to FIG. 1 to FIG. 3.

FIG. 5 shows a configuration of circuit components which can be used in control devices according to exemplary embodiments, in order to switch the first switching means 121 and the second switching means 122 into an on state. The illustrated circuit components can be used as a charging circuit 130 in the control device 100 from FIG. 4. For the purpose of charging the gates of the first switching means 121 and of the second switching means 122, charge is fed to the gates via a node 139. A diode 133 is connected to the input terminal 101. A further diode 134 is connected to the output terminal. Via the diode 133 or the diode 134, the gates of the first switching means 121 and of the second switching means 122 can be charged via a resistor 132. The charging circuit can comprise a capacitor 131, which is charged via the diode 133 and the further diode 134. The capacitor 131 stores charge for rapid charging of the gates of the first switching means 121 and of the second switching means 122, for example at the end of a phase gating or a phase cutting. A further terminal of the capacitor 131 can be connected to a ground potential P0.

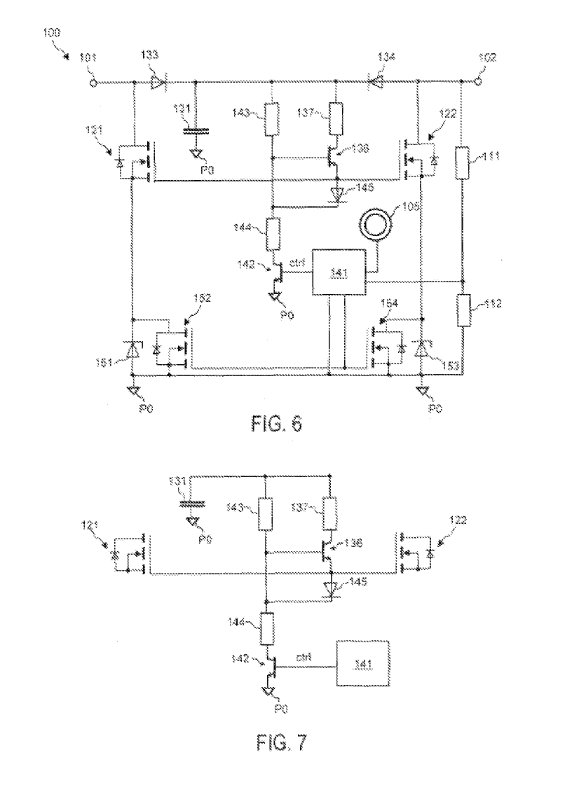

FIG. 6 is a circuit diagram of a control device 100 according to one exemplary embodiment. The control device 100 comprises a first switching means 121, a second switching means 122 and a control circuit, which can be configured as described with reference to FIG. 4. For the purpose of charging the gates of the first switching means 121 and of the second switching means 122, the configuration explained with reference to FIG. 5 is used. FIG. 7 shows a configuration of circuit components which can be used in control devices according to exemplary embodiments in order to switch the series circuit formed by the first switching means 121 and the second switching means 122 into an off state. Such a configuration is also used in the control device 100 from FIG. 6.

As explained with reference to FIG. 4, the control circuit is configured to increase a resistance of the series circuit formed by the first switching means 121 and the second switching means 122, for example by the series circuit being switched into an off state. The resistance of the line path through the series circuit formed by the first switching means 121 and the second switching means 122 is thereby increased. For the purpose of discharging the gates, the control circuit can produce a connection between the gates and ground, for example by driving a switch 142, which can be configured as a transistor 142. In addition, for the purpose of discharging the gates, the control circuit can switch a further switch 136, which can be configured as a further transistor, between the capacitor 131 and the gates of the first switching means 121 and of the second switching means 122 into an off state in order to temporarily prevent renewed charging of the gates.

The control circuit can be supplied with energy by a supply circuit comprising at least two zener diodes. In the case of the configuration illustrated in FIG. 6, a zener diode 151 and a power MOSFET 153 and also a further zener diode 155 and a further power MOSFET 154 are provided in order to supply the control circuit with energy. Further configurations are possible in order to generate an internal supply voltage for the control circuit. A voltage dropped across the second switching means 122 can be measured for the purpose of determining the zero crossing of the supply voltage. Such a measurement can be carried out while the series circuit formed by the first switching means 121 and the second switching means 122 is in a high-impedance state. For this purpose, the control circuit can detect the voltage dropped across the second switching means 122, for example, while it controls the series circuit formed by the first switching means 121 and the second switching means 122 such that the resistance of the series circuit is increased, in order to determine a zero crossing of the supply voltage on the basis of a zero crossing of the voltage thus detected.

In the embodiment illustrated, the control circuit, which can increase the resistance of the series circuit formed by the first switching means 121 and the second switching means 122, comprises an integrated circuit 141, a transistor 142 and a resistor 143. The integrated circuit 141 can be configured as a processor, microcontroller, controller or other integrated circuit. As described with reference to FIG. 5, the control device 100 can be configured such that the gates of the switching means 121, 122 are charged if a signal of the supply source is present at the input terminal 101. The integrated circuit 141 can generate and output a control signal ctrl in order to turn on the transistor 142. The resistor 144 acts as a pull-down resistor. The potential at the gates of the first switching means 121 and of the second switching means 122 is pulled in the direction of a ground potential P0. The gates of the first switching means 121 and of the second switching means 122 can be discharged via a diode 145, the resistor 144 and the transistor 142.

The control circuit 140 can prevent renewed charging of the gates of the first switching means 121 and of the second switching means 122, while the control signal ctrl is output. For this purpose, a further transistor 136, which is connected between the capacitor 131 and the gates of the first switching means 121 and of the second switching means 122, can undergo transition to an off state. In the case of the embodiment illustrated, a potential at the gate of the further transistor 136 is influenced by means of a voltage divider comprising the resistor 144 and a further resistor 143 such that the further transistor 136 is turned off while the control signal ctrl turns on the transistor 142. If the control signal ctrl is no longer generated, that is to say if, for example, the potential at the corresponding output of the integrated circuit 141 returns to a lower value, the transistor 142 is turned off. Charge for renewed charging of the gates of the first switching means 121 and of the second switching means 122 can be provided by the capacitor 131. The gates of the first switching means 121 and of the second switching means 122 can be charged via the further transistor 136 and a resistor 137 if the supply source provides a signal at the input terminal 101 and the integrated circuit 141 does not control the transistor 142 such that the potential at the gates of the first switching means 121 and of the second switching means 122 is influenced in order to increase the resistance of the series circuit.

A series circuit formed by resistors 111, 112 can be connected between the input terminal and the output terminal in order to carry out a voltage measurement. As is described in even greater detail with reference to FIG. 8 to FIG. 10, a zero crossing of the supply voltage can thus be identified, while the series circuit formed by the first switching means 121 and the second switching means 122 is switched into an off state.

One possible exemplary embodiment of a control device 100 is explained below. The control device 100 comprises a first switching means 121, a second switching means 122 and a control circuit, which can be configured as described with reference to FIG. 7. The control circuit comprises an integrated circuit 141. Only the circuit components of the control device 100 which are relevant to the understanding of the invention are described in detail below.

The control device comprises a charging circuit for charging the gates of the first switching means 121 and of the second switching means 122. The charging circuit comprises a capacitor 131 and diodes 133, 134. The capacitor 131 is charged via the diodes 133, 134 if the supply source supplies a supply voltage. The charging circuit furthermore comprises a transistor 136 connected to the gates of the first switching means 121 and of the second switching means 122. The charging circuit keeps the series circuit formed by the first switching means 121 and the second switching means 122 in an on state, i.e. in a low-impedance state, if a signal is present at the input terminal 101 and the control circuit does not discharge the gates of the first switching means 121 and of the second switching means 122.

In order to switch the series circuit formed by the first switching means 121 and the second switching means 122 into an off state, the integrated circuit 141 controls a transistor 142. An output signal of the integrated circuit 141 controls a potential at the gate of the transistor 142. If the transistor 142 is switched into an on state, the gate voltage of the transistor 136 is pulled in the direction of the ground potential by means of a voltage divider comprising resistors 143 and 144. The transistor 136 is turned off. Renewed charging of the gates of the first switching means 121 and of the second switching means 122 by the capacitor 131 is suppressed in this way. The gates of the first switching means 121 and of the second switching means 122 are discharged, for example via a diode 145 and via the transistor 142.

In order to end the selective switching of the series circuit formed by the first switching means 121 and the second switching means 122 into the off state, the integrated circuit 141 no longer outputs a signal to the gate electrode of the transistor 142. The transistor 142 is turned off. The gates of the first switching means 121 and of the second switching means 122 are charged by the capacitor 131 via the transistor 136. The series circuit formed by the first switching means 121 and the second switching means 122 correspondingly reverts to an on state, in which it has a lower resistance. The use of the capacitor 131 makes it possible to achieve a rapid return to the on state.

In order to generate phase gating and/or phase cutting of half-cycles or full cycles of the supply voltage, the line path between input terminal and output terminal is switched with high impedance in specific time windows. As described with reference to FIG. 3, the corresponding time windows are in a predefined temporal relation with zero crossings of the supply voltage. The control device 100 can be configured to automatically determine the instant at which a zero crossing of the supply voltage occurs. If the control device 100 also has a terminal for the neutral conductor 20, a zero crossing can be determined directly by the measurement of the voltage between the input terminal 101 and the neutral conductor 20. If the control device 100 does not have a terminal for the neutral conductor 20, the control device 100 can carry out a procedure for determining the zero crossing of the supply voltage before a data packet is transmitted via the load line 40. A realization of such a procedure is described in greater detail with reference to FIG. 8 to FIG. 10. Generally, the control device 100 can be configured such that a line path between the input terminal 101 and the output terminal 102 of the control device 100 is switched into a high-impedance state in a targeted manner for a time interval. A current flow from the input terminal 101 to the luminaire 50 via the load line 40 can thus be interrupted or greatly reduced. A voltage dropped in the control device 100 is monitored during this time interval. A zero crossing of said voltage corresponds to a zero crossing of the supply voltage provided by the supply source.

FIG. 8 is a circuit diagram of the control device 100 according to one exemplary embodiment for elucidating the identification of the zero crossing. A series circuit formed by a first switching means 121 and a second switching means 122 is connected between the input terminal 101 and the output terminal 102 of the control device 100.

For determining the zero crossing of the supply voltage, the control circuit 110 controls the first switching means 121 and the second switching means 122 such that at least one of the switching means 121, 122 is in a high-impedance state. The line path between the input terminal 101 and the output terminal 102 is switched into a high-impedance state. If the operating device of the luminaire supplied with energy via the output terminal 102 has an interference-suppression capacitor, the latter can then be discharged. The interference-suppression capacitor of the operating device can be discharged via the illuminant, in particular.

The control circuit 110 can be configured such that it identifies a zero crossing of a voltage in the control device 100, while the series circuit formed by the first switching means 121 and the second switching means 122 is switched into the off state. For this purpose, the voltage dropped at a zener diode 112 or at a resistor 112 in the control device 100 can be monitored for example at a measuring point 113. The zener diode or resistor 112 can be connected with a resistor 111 in a series circuit between the input terminal 101 and the output terminal 102. The voltage measurement can also be carried out across the design-governed integrated diode of one of the switching means. While the interference-suppression capacitor of the operating device is discharged, the detected voltage approaches the supply voltage. A zero crossing of the voltage detected in the control device 100, while the series circuit formed by the first switching means 121 and the second switching means 122 is switched into the off state, corresponds to a zero crossing of the supply voltage.

After the zero crossing of the supply voltage has been identified, the control circuit 110 ends the control process with which the series circuit formed by the first switching means 121 and the second switching means 122 was switched into the off state. By way of example, both MOSFETs can return to an on state for this purpose. The resistance of the line path between the input terminal 101 and the output terminal 102 is thus reduced in order to allow a current flow between supply source 10 and luminaire 50 via the control device 100. The control circuit 110 can switch one of the switching means 121, 122 into the off state in each case in a predefined time window for a sequence of half-cycles of the supply voltage in order to generate phase gating or phase cutting of half-cycles of the supply voltage and thus to transmit a sequence of data bits.

The control of the series circuit formed by the first switching means 121 and the second switching means 122 in such a way that said series circuit is switched into a high-impedance state in order to determine the zero crossing of the supply voltage can be carried out in a manner coordinated with the current flowing via the load line 40. For this purpose, the control circuit 110 can monitor the current. The control circuit 110 can switch the series circuit formed by the first switching means 121 and the second switching means 122 into the off state upon a zero crossing of the current and can subsequently determine the instant at which the voltage detected in the control device has a first zero crossing. The identification of the zero crossing of the supply voltage can take place in a time interval which is defined depending on a zero crossing of the current. The identification of the zero crossing of the supply voltage can take place in particular in a time interval which starts upon a zero crossing of the current which flows through the control device to the operating device of the illuminant.

FIG. 9 is a flowchart of a method 210 for data transmission via a load line. The method 210 can be performed automatically by the control device 100. In step 201, an event that initiates the performance of the method for data transmission can be monitored. As explained with reference to FIG. 8, the actuation of a setting element can be monitored, for example. As soon as an event that initiates the transmission of a data packet via the load line is identified, step 211 involves monitoring when the current flowing via the load line 40 has a zero crossing.

In step 212, a zero crossing of the current initiates a control in such a way that the series circuit formed by the first switching means 121 and the second switching means 122 is switched into an off state. By way of example, a MOSFET can be switched into a high-impedance state for this purpose. Step 213 involves monitoring when a voltage dropped in the control device 100 has a zero crossing. For this purpose, by way of example, a voltage dropped across the zener diode 112 or resistor 112 can be detected and the zero crossing of said voltage can be identified, as has been described with reference to FIG. 8. The series circuit formed by the first switching means 121 and the second switching means 122 remains switched into the off state until the zero crossing of the voltage detected in the control device 100 is identified. This instant corresponds to a zero crossing of the supply voltage.

After the zero crossing of the supply voltage has been determined, a plurality of data bits is transmitted in step 214. Phase gating and/or phase cutting of half-cycles of the supply voltage can be generated for this purpose. The time windows in which the switching means 106 is in each case switched into the off state in order to generate a phase gating and/or phase cutting are chosen depending on the zero crossing of the supply voltage identified in step 213 such that they are in a predefined temporal relation with zero crossings of the supply voltage. The data packet can comprise for example ten data bits or more than ten data bits. During the transmission of a data packet, for example in five full cycles of the supply voltage, the zero crossing of the supply voltage need not be determined anew. The procedure for determining the phase angle of the supply voltage can be repeated, for example, if a new data packet is transmitted or if the time that has elapsed since the last determination of the zero crossing of the supply voltage exceeds a threshold value.

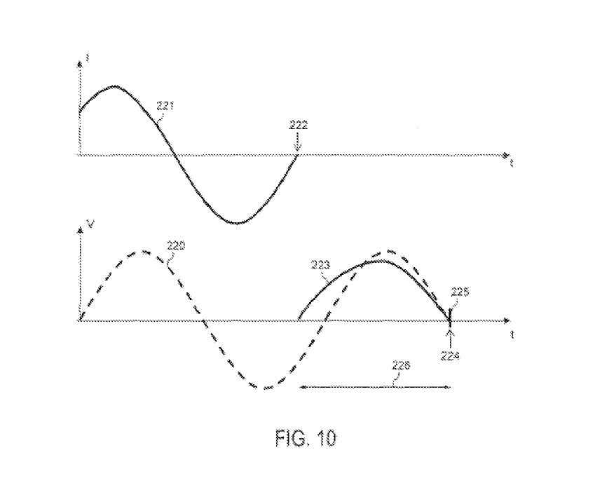

FIG. 10 is a diagram for further elucidation of the functioning of the control device according to exemplary embodiments when determining the zero crossing of the supply voltage. After an event that initiates the procedure for determining the zero crossing of the supply voltage, a zero crossing 222 of a current 221 that flows via the load line 40 is identified. Upon the zero crossing 222 of the current 221, the control circuit 110 controls the series circuit formed by the first switching means 121 and the second switching means 122 such that said series circuit acquires high impedance. The line path between input terminal 101 and output terminal 102 of the control device 100 thereby acquires high impedance. In a time interval 226 in which the series circuit formed by the first switching means 121 and the second switching means 122 remains switched into the off state, the first zero crossing of a voltage 223 is identified. The interference-suppression capacitor of the operating device of the illuminant is discharged during the time interval 226. The voltage 223 detected in the control device, which voltage initially has a phase shift with respect to the supply voltage, approaches the supply voltage with the discharging of the interference-suppression capacitor of the operating device. Upon the zero crossing 224 of the voltage 223, the supply voltage also has a zero crossing. The instant 225 thus determined can be used to generate phase gating or phase cutting for a sequence of half-cycles of the supply voltage. The switching means can be switched into the on state again at the instant 225.

In order to prevent the illuminant from ceasing to shine during the time interval 226, the operating device can have a charging capacitor. The charging capacitor can be configured such that it can maintain operation of the illuminant at 100% brightness during a discharge time of the interference-suppression capacitor of the operating device.

While control devices and methods according to exemplary embodiments have been described in detail with reference to the figures, modifications can be realized in further configurations. By way of example, other controllable power switches can be used instead of power MOSFETs. Instead of n-channel MOSFETs that are switched into a high-impedance state by discharge of the gates, use can also be made of p-channel MOSFETs. The control circuit would accordingly bring about charging of the gates of the switching means in order to increase the resistance of the line path between input terminal and output terminal. While the control device can comprise two switching means in a series circuit which are configured for generating a phase gating both in the case of half-cycles of the supply voltage having a positive sign and in the case of half-cycles having a negative sign, in further exemplary embodiments the data transmission can be effected such that a phase gating or phase cutting is generated only for half-cycles having one specific sign. Bipolar transistors that were described with reference to some exemplary embodiments can also be replaced by other controllable switching means.

While control devices and methods according to exemplary embodiments can be used for transmitting dimming commands and/or for color control, target values for other manipulated variables can also be transmitted. In all of the exemplary embodiments, the data transmission can take place once the illuminant is already emitting light. The data transmission can take place via the load line without the illuminant ceasing to shine. A change in the brightness, color or other manipulated variable can be carried out by the operating device after the data packet has been completely transmitted and while no more phase gating and/or phase cutting whatsoever need be modulated onto the supply voltage.

While the coding of data bits by the generation of a phase gating or phase cutting has been described, the supply voltage can also be influenced in some other way in order to transmit a sequence of data bits with a sequence of half-cycles of the supply voltage. By way of example, the supply voltage provided to the operating device by the control device can also be decreased substantially to zero during a time window which lies neither at the beginning nor at the end of a half-cycle of the supply voltage.

In all of the embodiments, a bridging contact of the setting element can bridge the input terminal and the output terminal of the control device as long as the setting element is not actuated. What can be achieved in this way is that a voltage supply of the control circuit is effected only upon the actuation of the setting element, such that a power consumption of the control device can be reduced.

Devices and methods according to exemplary embodiments can be used, in particular, for controlling luminaires which comprise LEDs, without being restricted thereto.

1. A control device for data transmission via a load line (40) to a load (52), for transmitting a data packet to an operating device (52) for an illuminant (54), wherein the control device (100) has an input terminal (101) for coupling to a supply source (10) and an output terminal (102) for coupling to the load line (40), wherein the control device (100) comprises:
a first switching means (121) and a second switching means (122), which are connected in a series circuit between the input terminal (101) and the output terminal (102), and
a control circuit (110; 140; 141-145), which is coupled to the first switching means (121) and the second switching means (122) and which is configured to generate a control signal (ctrl) for controlling the first switching means (121) and/or the second switching means (122) for transmitting data bits.

2. The control device as claimed in claim 1, wherein the first switching means (121) and the second switching means (122) are configured to conductively connect the input terminal (101) to the output terminal (102) if a signal is present at the input terminal (101) and the control circuit (110; 140; 141-145) does not generate the control signal (ctrl).

3. The control device as claimed in claim 2, wherein the control circuit (110; 140; 141-145) is configured to influence a potential at a gate of the first switching means (121) and at a gate of the second switching means (122) only if the control device (100) generates the control signal (ctrl).

4. The control device as claimed in claim 1, further comprising circuit components (130; 131-134) coupled to the input terminal (101) and serving for charging a gate of the first switching means (121) and a gate of the second switching means (122).

5. The control device as claimed in claim 4, wherein the control circuit (110; 140; 141-145) is configured to cause a discharge of the gate of the first switching means (121) and of the gate of the second switching means (122) by generating the control signal (ctrl).

6. The control device as claimed in claim 4, wherein the control circuit (110; 140; 141-145) is configured to control a discharge of the gate of the first switching means (121) and of the gate of the second switching means (122) via a pull-down resistor (144).

7. The control device as claimed in claim 1, further comprising at least one energy storage means (131) configured to charge a gate of the first switching means (121) and a gate of the second switching means (122).

8. The control device as claimed in claim 7, wherein the control circuit (110; 140; 141-145) is configured to control a further switching means (136), which is connected between the energy storage means (131) and the gates of the first switching means (121) and of the second switching means (122).

9. The control device as claimed in claim 1, wherein the control circuit (110; 140; 141-145) is configured to switch the series circuit formed by the first switching means (121) and the second switching means (122) into a high-impedance state multiply for the purpose of transmitting a sequence of data bits.

10. The control device as claimed in claim 9, wherein the control circuit (110; 140; 141-145) is configured to identify a phase angle of a supply voltage (220; 230) of a supply source (10) and to generate the control signal (ctrl) in predefined time windows before or after zero crossings of the supply voltage (220; 230).

11. The control device as claimed in claim 10, wherein the control circuit (110; 140; 141-145) is configured to switch the series circuit formed by the first switching means (121) and the second switching means (122) into the high-impedance state twice per full cycle of the supply voltage (220; 230).

12. The control device as claimed in claim 9, wherein the control circuit is configured to switch the series circuit formed by the first switching means (121) and the second switching means (122) into the high-impedance state both in the case of a half-cycle (231, 233) of the supply voltage having a positive sign and in the case of a half-cycle (232, 234, 236, 238) of the supply voltage having a negative sign.

13. A method for data transmission from a control device (100) to a load (52), for transmitting a data packet to an operating device (52) for an illuminant (54),
wherein phase gating and/or phase cutting (241-244, 246, 248) of half-cycles (231-234, 236, 238) of a supply voltage are generated by means of the control device (100) as claimed in claim 1.

14. A lighting system, comprising:
at least one operating device (52) for an illuminant (54), and
a control device (100) as claimed in claim 1, which is coupled to the at least one operating device (52) via a load line (40).

15. The lighting system as claimed in claim 14, wherein the at least one operating device (52) comprises at least one LED converter.
